(19) United States
(12) Patent Application Publication
(10) Pub. No.: US 2015/0236245 A1
(43) Pub. Date: Aug. 20, 2015

(54) SEMICONDUCTOR PACKAGE AND METHOD THEREOF

(71) Applicant: ChipMOS Technologies, Inc., Hsinchu (TW)

(72) Inventor: Shih-Wen CHOU, Hsinchu (TW)

(21) Appl. No.: 14/553,371

(22) Filed: Nov. 25, 2014

(30) Foreign Application Priority Data
Feb. 14, 2014 (TW) 103104862

(51) Int. Cl. H01L 43/02; H01L 43/12; H01L 43/08

(52) U.S. Cl. CPC H01L 43/02; H01L 43/08; H01L 43/12

(57) ABSTRACT

A semiconductor package and manufacturing method thereof are disclosed. The semiconductor package includes a package carrier, a chip, a film, a first shielding metal plate and an encapsulating material. The package carrier has at least one conductive component. The chip has an active surface and a corresponding back surface. The back surface of the chip is attached to the package carrier. At least one contact point is disposed on the active surface and is electrically coupled to the conductive component by a wire. The film is disposed on the active surface and covers a portion of the wire. The first shielding metal plate is disposed on the film. The encapsulating material covers the chip, the wire, at least one portion of the package carrier, the film and at least one portion of the first shielding metal plate.

### PRIORITY CLAIM

This application claims the benefit of the filing date of Taiwan Patent Application No. 103104862, filed Feb. 14, 2014, entitled “SEMICONDUCTOR PACKAGE AND METHOD THEREOF,” and the contents of which are hereby incorporated by reference in their entirety.

### FIELD OF THE INVENTION

The present invention relates to a semiconductor package and method thereof, and more particularly, to a magneto-electric resistive random access memory chip package and method thereof.

### BACKGROUND

A magneto-electric resistive random access memory (MRAM) chip mainly uses the self-spin characteristic of an electron in recording a “0” and “1” of a signal by the magneto resistive changes which is generated by the difference in the magnetization direction in the free layer of magnetic structure. The MRAM chip has the same working principle in saving data to a hard disk drive, where the saved data is permanently saved and the data cannot be altered unless there is external magnetic field affection. The MRAM chip has the same characteristics in low energy consumption and fast response with static random-access memory (SRAM) and the same characteristic in high density with dynamic random access memory (DRAM). In other words, the MRAM comprises the advantage of the SRAM and the DRAM and the opportunity of mass application of the MRAM is just around the corner.

Because of the operating characteristics of the MRAM, isolated unnecessary or non-read-write operating magnetic fields are needed. Therefore, a magnetic field shielding protection is needed in an MRAM package. The known external magnetic field shielding structure so far is using a metallic layer for shielding a chip to achieve the effect of magnetic field shielding. There are two ways of providing magnetic field shielding. One is the metallic layer attaching to the active surface of a chip directly, and the other is forming the metallic layer outside of the encapsulating material. The disadvantage of the first way of providing magnetic field shielding is that the metallic layer cannot provide the shielding protection to the wires links on the chip as the external magnetic field can affect the chip via the wire-bonding region and change the magneto resistance. The second way usually lets a portion of wires dispose outside of the encapsulating material, and sputtering coats the metallic layer outside of the encapsulating material. However, the second way needs specialized equipment, a complicated process, and makes wires sweep easily. While cutting the encapsulating material, the cutter will make contact with the metallic layer, then the burr and the wearing of the cutter will appear easily.

### SUMMARY OF THE INVENTION

Accordingly, one aspect of the present invention is to provide a semiconductor package and method thereof to improve the disadvantages of prior art.

Accordingly, another aspect of the present invention is to provide a semiconductor package and method thereof which can cover the wire-bonding region, and the wires to prevent the wires from sweeping.

Accordingly, the other aspect of the present invention is to provide a semiconductor package and method thereof which does not need specialized equipment, and simplifies the process.

According to the aspects of the present invention above, the present invention provides a semiconductor package comprising a package carrier, a chip, a film, a first shielding metal plate, and an encapsulating material, wherein the package carrier has at least one conductive component; the chip has an active surface and a corresponding back surface, and the back surface of the chip is attached to the package carrier. Wherein at least one contact point is disposed on the active surface and electrically coupled to the conductive component by a wire; the film is disposed on the active surface and covering a portion of the wire; the first shielding metal plate is disposed on the film; the encapsulating material covering the chip, the wire, at least one portion of the package carrier, the film and at least one portion of the first shielding metal plate.

According to an embodiment, the semiconductor package further comprises a second shielding metal plate disposed between the chip and the package carrier, wherein the material of the first and the second shielding metal plate comprises iron-nickel alloy.

According to the embodiment of the semiconductor package, wherein the package carrier comprises a lead frame and the conductive component is a lead.

According to another embodiment of the semiconductor package, wherein the package carrier comprises a circuit board and the conductive component is a circuit.

According to the embodiment of the semiconductor package, wherein the chip comprises a magneto resistive random access memory (MRAM).

According to the aspects of the present invention above, the present invention provides a semiconductor package method comprising: providing a package carrier, with the package carrier having at least one conductive component; providing a chip, with the chip having an active surface and a corresponding back surface and the back surface of the chip being attached to the package carrier, wherein the active surface has at least one pad; electrically coupling the pad to the conductive component by a wire; providing a first shielding metal plate, with the first shielding metal plate having a film and is disposed on the active surface for covering the active surface and a portion of the wire; and providing an encapsulating material for covering the chip, the wire, at least one portion of the package carrier, the film and at least one portion of the first shielding metal plate.

According to an embodiment, the semiconductor package method before providing the chip, further comprising: attaching a second shielding metal plate to the package carrier with the back surface of the chip attached to the second shielding metal plate.

According to an embodiment, the semiconductor package method, wherein the material of the first and the second shielding metal plate comprises iron-nickel alloy.

According to an embodiment, the semiconductor package method, wherein the chip comprises a magneto resistive random access memory (MRAM).

According to the semiconductor package and method thereof provided by the present invention, the shielding metal plates can cover the wire-bonding region and the wires via the film to prevent wire sweeping. The shielding metal plates cover the active surface of the chip without using specialized equipment to simplify the process. The advantage and spirit of the invention may be understood by the following recitations together with the appended drawings.

### BRIEF DESCRIPTION OF THE DRAWINGS

FIG. 1 to FIG. 5 are section schematic diagrams of each process step of the semiconductor package method according to the present invention.

FIG. 6 is a section schematic diagram of a semiconductor package according to one embodiment of the present invention.

FIG. 7 is a section schematic diagram of a semiconductor package according to another embodiment of the present invention.

### DETAILED DESCRIPTION

The embodiments and the practical applications of the present invention will be described in the following paragraphs, so as to sufficiently explain the characteristics, spirits, and advantages of the invention.

It is worth noting that these embodiments are merely representative of the embodiments of the present invention, wherein an example of a specific method, apparatus, conditions, materials, etc. is not intended to limit the invention or the corresponding embodiment of the invention.

The following embodiments of the present invention of the semiconductor package and method thereof mainly focus on the package of an MRAM; however, it is not limited to the chip package mentioned above. Any chip that needs magnetic shielding can use the package structure and method of the present invention.

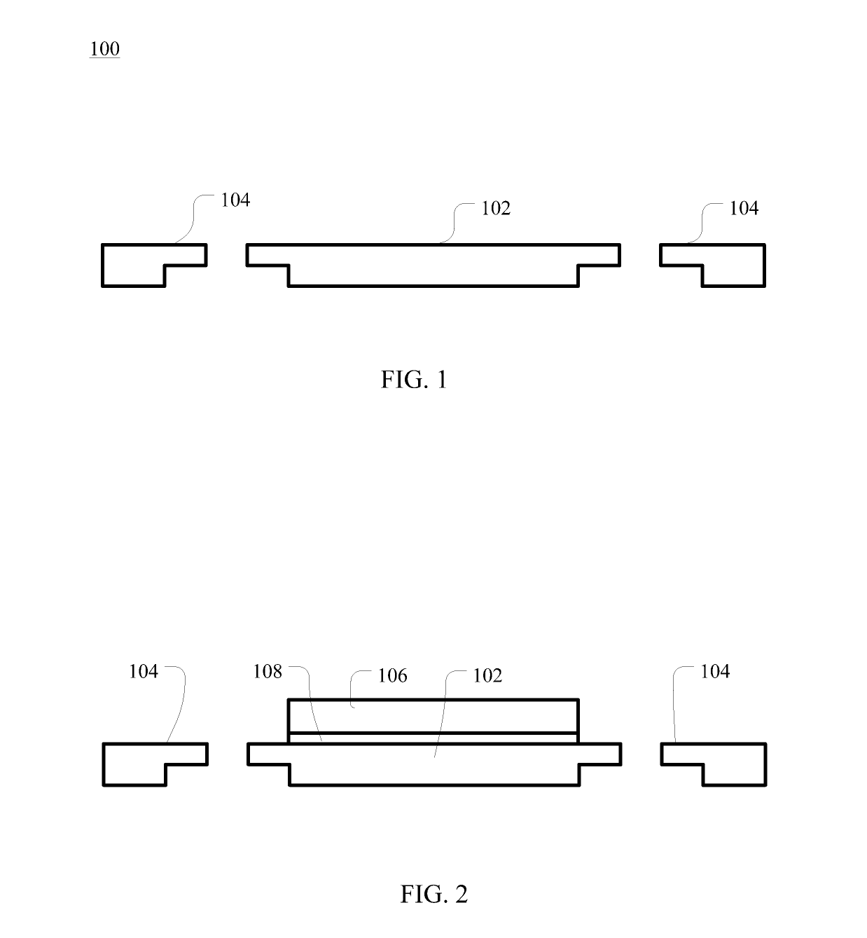

Please refer to FIG. 1 to FIG. 5, which are the section schematic diagrams of each process step of the semiconductor package method according to the present invention. According to an embodiment of the present invention, the semiconductor package of the present invention is constructed on a package carrier, and the package carrier has at least one conductive component. For example, in the embodiment, a lead frame is treated as the package carrier, as shown in FIG. 1, where the lead frame 100 includes a chip placement 102 and multiple leads 104 (the conductive component). The materials of the lead frame 100 include copper, copper alloy, iron alloy, iron-nickel alloy, copper-iron alloy, and iron-cobalt-nickel alloy. The surface of the lead frame 104 can be partially or completely coated, and the coating material includes copper, nickel, silver, tin alloy, palladium, platinum, and gold.

Please refer to FIG. 2 which shows the strengthening of the magnetic shielding of the back surface of a chip, where it is best to attach a shielding metal plate 106 (the second shielding metal plate), such as an iron-nickel alloy metal plate. The shielding metal plate 106 can provide an excellent magnetic shielding effect. The shielding metal plate 106 attaches to the chip placement 102 via an adhesion layer 108. The adhesion layer 108 is capable of utilizing a heat conductive adhesive where the heat conductive adhesive can strengthen the heat dissipation of the back surface of the chip. The adhesion layer 108 can also be die attach film (DAF) or tape. FIG. 3 shows a chip 110, for example an MRAM, attached to the shielding metal plate 106, where the chip 110 has an active surface 112 and a corresponding back surface 114. The active surface 112 has at least one contact point 116, for connecting internal components to external circuitry and the back surface 114 attaches to the shielding metal plate 106 via an attach layer 118. The attach layer 118 is capable of utilizing a heat conductive adhesive where the heat conductive adhesive can strengthen the heat dissipation of the back surface of the chip. The adhesion layer 108 can also be die attach film (DAF) or tape. Then a wire bonding process is used, where the wire bonding process is electrically coupled by the pad 116 to the leads 104 by a wire 120, for example, a gold wire, a copper wire, silver wire, or alloy wire thereof.

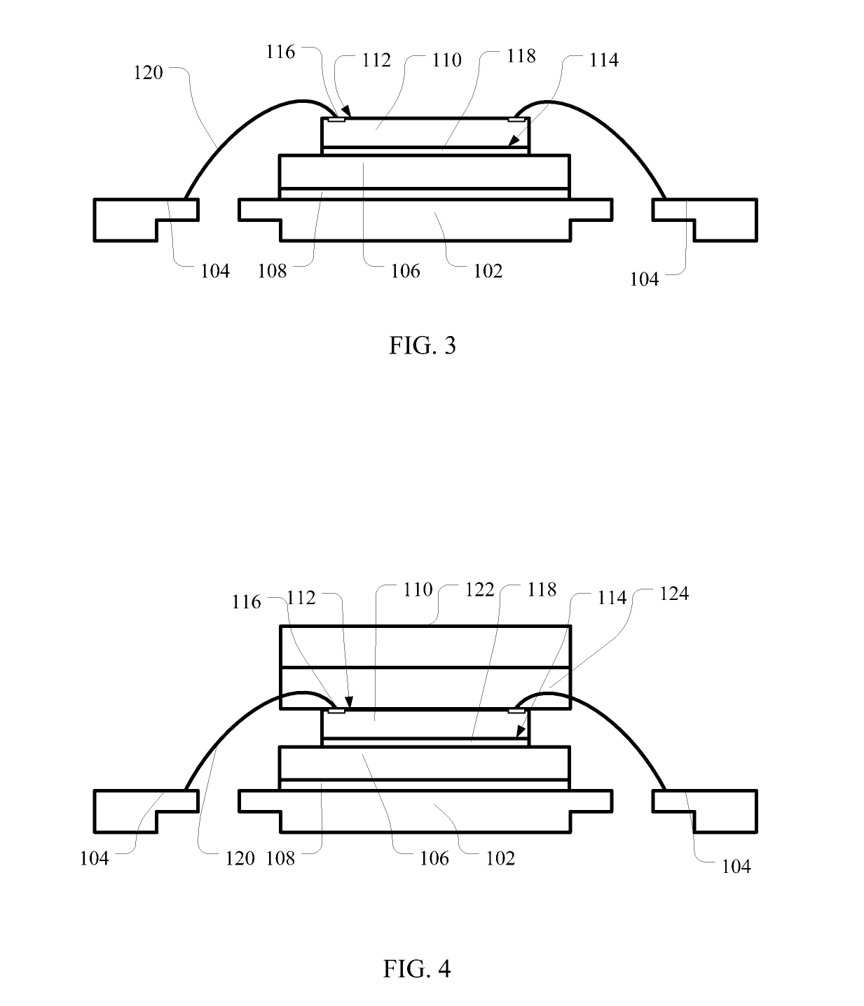

As shown in FIG. 4, a first shielding metal plate 122 is provided, where the first shielding metal plate 122 has a film 124. The film 124 can be pre-forming on the first shielding metal plate 122. Then, the first shielding metal plate 122 is cut with the film 124 into single components. The first shielding metal plate 122 is then covered on the active surface 112 and the film 124 covers the active surface 112 and a portion of the wire 120. The film 124 can be a non-conductive paste with wire penetrating capability that is also called film over wire (FOW). When the first shielding metal plate 122 is covered on the active surface 112, a portion of the wire 120 can penetrate and cover the film 124. Then, the heating procedure is carried out to heat the single package for curing the film 124.

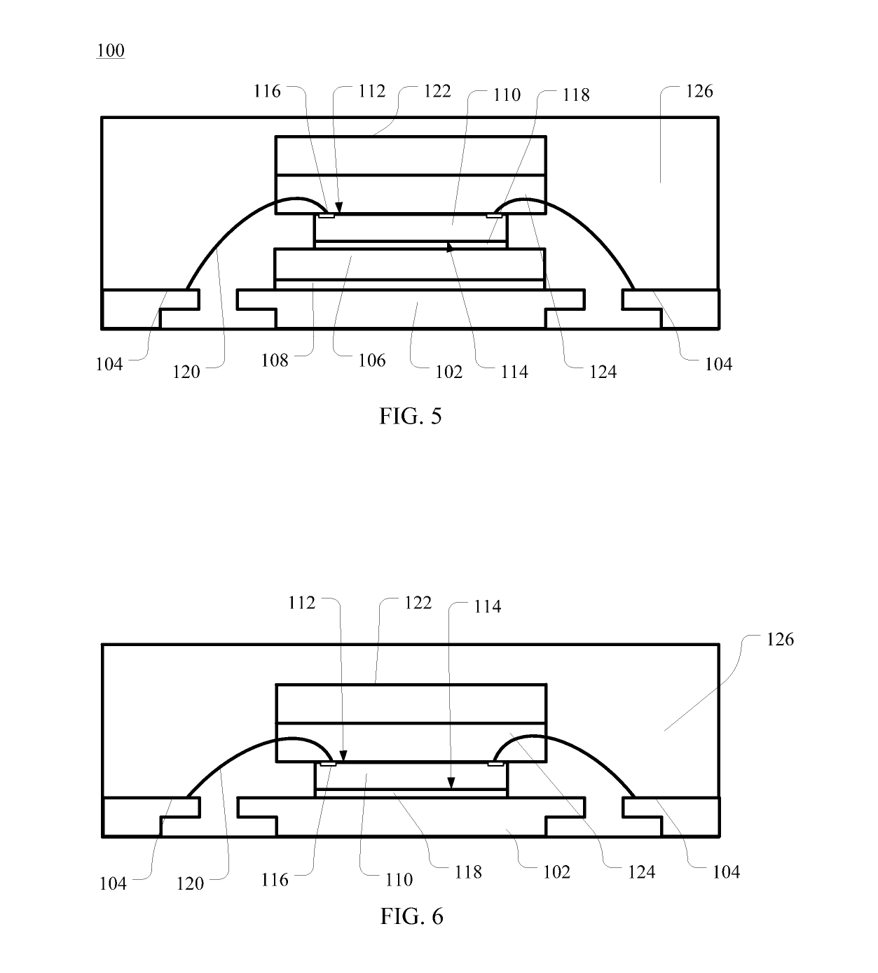

As shown in FIG. 5, an encapsulating step is preceded. The step describes encapsulating the chip 106, the wire 120, and a portion of the package carrier 106 (with a portion of the chip placement 102 and the leads 104) with an encapsulating material 126. More specifically, the encapsulating material 126 is capable of insulating the encapsulating compound. The component shown in the FIG. 4 is placed in a cavity (not shown in the FIG. 4). Then, the encapsulating material 126 is filled in the cavity and encapsulates the component shown in the FIG. 4, and exposes the lower surfaces of the chip placement 102 and the leads 104. The exposed lower surfaces not only helps the chip 106 dissipate heat, but also to be used as an external ground contact point. The disposed lower surfaces of the leads 104 are used as an external ground contact point.

Therefore, in the embodiment, the semiconductor package of the present invention comprises: the package carrier 100, the chip 110, the first shielding metal plate 122, the second shielding metal plate 106, and the encapsulating material 126. As shown in FIG. 5, the package carrier 100 has at least one conductive component (the leads 104); the chip 110 has an active surface 112 and a corresponding back surface 114. The chip 110 is attached to the second shielding metal plate 106 with the back surface 114 of the chip 110, and then attached to the package carrier 100 (for example, the chip placement 102). Wherein at least one contact point 116 is disposed on the active surface 112 and electrically coupled to the conductive component (for example, the leads 104) by a wire 120. The film 124 is disposed on the active surface 112 and covers a portion of the wire 120. The first shielding metal plate 122 is disposed on the film 124; the encapsulating material 126 covers the chip 110, the wire 120, at least one portion of the package carrier 100, the film 124, the second shielding metal plate 106 and the first shielding metal plate 122.

It is worth noting that the first shielding metal plate 122 and the second shielding metal plate 106 can have the same design and volume, and in some embodiments, the first shielding metal plate 122 and the second shielding metal plate 106 can have a different design and volume.

Please refer to FIG. 6, which is a section schematic diagram of a semiconductor package according to one embodiment of the present invention. It is worth noting that in some embodiments, the material used for the package carrier 100 (as shown in FIG. 1), especially the material of the chip placement 102 can be a magnetic shielding material, for example, an iron-nickel alloy or some material like it. The second shielding metal plate 106 in the embodiment above (as shown in FIG. 5) can be omitted So as shown in FIG. 6, the back surface 114 of the chip 110 is attached directly to the chip placement 102 via the attach layer 118. The other structures are similar to the embodiment which is shown in FIG. 5. In that embodiment, the first shielding metal plate 122 provides the magnetic field shielding protection on the active surface 112 of the chip 110, and the chip placement 102 provides the magnetic field shielding protection on the back surface 114 of the chip 110.

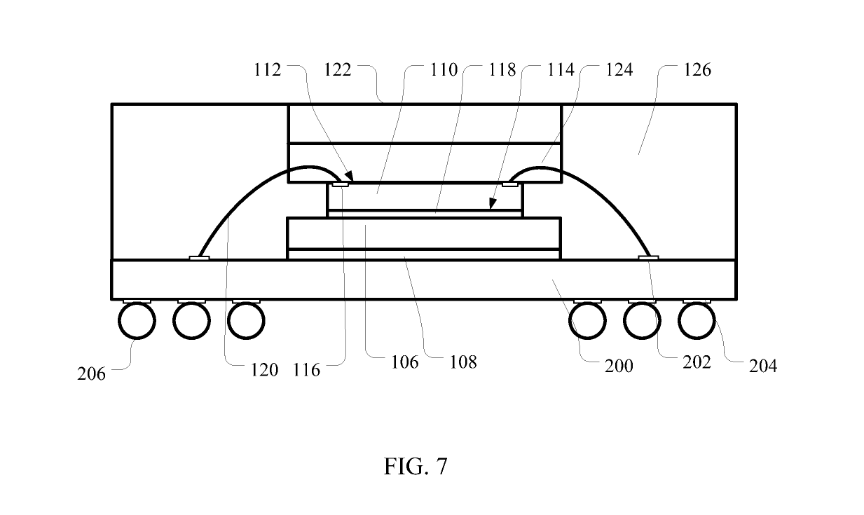

Please refer to FIG. 7, which is a section schematic diagram of a semiconductor package according to another embodiment of the present invention. In the semiconductor package of the present invention, the choice of the package carrier in addition to the lead frame can also be other types of carrier packages. For example, as shown in FIG. 7, in some embodiments the package carrier can also be a ball grid array substrate (BGA substrate) 200. The known BGA substrate 200 consists of printed circuit board (PCB) in high density, and treats the BGA substrate 200 as the medium between the chip and the external circuit connection. The electrically connected path to the external circuit includes a bonding pad 202 which is connected to the chip, multiple layers of PCB (not shown in FIG. 7), a ball pad 204, and a solder ball 206. Therefore, in the BGA substrate 200, the conductive component mentioned above consists of the bonding pad 202, the ball pad 204, and the solder ball 206. As shown in FIG. 7, the contact point 116 of the chip 110 connects to the bonding pad 202 via the wire 120, and then connects to the external circuit via the ball pad 204 and the solder ball 206.

It is worth noting that the first shielding metal plate 122 not only provides the magnetic field shielding protection on the active surface 112 of the chip 110, but also provides an excellent heat dissipation path because of the metal material of the first shielding metal plate 122. Therefore, in some embodiments of the present invention, to strengthen the heat dissipation effect, the encapsulating material 126 optionally covers a portion of the first shielding metal plate 122 that is exposed to the outside surface to increase the heat dissipation effect, as shown in FIG. 7, wherein the semiconductor package of the present invention is formed by disposing a plural of the chips 110 on the package carrier 100. After the encapsulating step is completed, then the semiconductor package with the plural of the chips 110 is cut into the semiconductor package with the single chip 110. The structures illustrated in the figures are schematic diagrams, and they are not the limitation of the present invention.

In summary, in the semiconductor package and method thereof of the present invention, the shielding metal plate can cover the wire and wire-bonding region via the film, while covering the whole active surface of the chip. The shielding metal plate provides an excellent magnetic field shielding effect, and prevents wire sweeping. In addition, the process of covering the shielding metal plate to the active surface of the chip does not need a special entity which simplifies the whole process of semiconductor packaging.

With the example and explanations above, the features and spirits of the invention will be hopefully well described. Those skilled in the art will readily observe that numerous modifications and alterations of the device may be made while retaining the teachings of the invention. Accordingly, the above disclosure should be construed as limited only by the metes and bounds of the appended claims.

1. A semiconductor package comprising:
a package carrier, having at least one conductive component;
a chip, having an active surface and a corresponding back surface, the back surface of the chip attached to the package carrier, wherein at least one contact point is disposed on the active surface and electrically coupled to the conductive component by a wire;
a film, disposed on the active surface and covering a portion of the wire;
a first shielding metal plate disposed on the film; and
an encapsulating material covering the chip, the wire, at least one portion of the package carrier, the film and at least one portion of the first shielding metal plate.

2. The semiconductor package of claim 1, wherein the material of the first shielding metal plate comprises iron-nickel alloy.

3. The semiconductor package of claim 1, further comprising a second shielding metal plate disposed between the chip and the package carrier.

4. The semiconductor package of claim 3, wherein the material of the second shielding metal plate comprises iron-nickel alloy.

5. The semiconductor package of claim 1, wherein the package carrier comprises a lead frame, and the conductive component is a lead.

6. The semiconductor package of claim 1, wherein the package carrier comprises a substrate of a circuit board, and the conductive component is a circuit.

7. The semiconductor package of claim 1, wherein the chip comprises a magneto resistive random access memory (MRAM).

8. The semiconductor package of claim 1, wherein the film can be a non-conductive paste with wire penetrating capability.

9. The semiconductor package of claim 8, wherein the film comprises a film over wire (FOW).

10. The semiconductor package of claim 8, wherein the film can be pre-formed on the first shielding metal plate.

11. A semiconductor package method comprising:
providing a package carrier, the package carrier having at least one conductive component;
providing a chip, the chip having an active surface and a corresponding back surface, the back surface of the chip attached to the package carrier, wherein the active surface has at least one contact point;
electrically coupling the contact point to the conductive component by a wire;
providing a first shielding metal plate, the first shielding metal plate having a film and disposed on the active surface for covering the active surface and a portion of the wire; and
providing an encapsulating material for covering the chip, the wire, at least one portion of the package carrier, the film and at least one portion of the first shielding metal plate.

12. The semiconductor package method of claim 11, before providing the chip, further comprising:
attaching a second shielding metal plate to the package carrier, and the back surface of the chip attached to the second shielding metal plate.

13. The semiconductor package method of claim 11, wherein the material of the first shielding metal plate comprises iron-nickel alloy.

14. The semiconductor package method of claim 12, wherein the material of the second shielding metal plate comprises iron-nickel alloy.

15. The semiconductor package method of claim 11, wherein the chip comprises a magneto resistive random access memory (MRAM).

16. The semiconductor package method of claim 11, wherein the film can be a non-conductive paste with wire penetrating capability.

17. The semiconductor package method of claim 16, wherein the film comprises a film over wire (FOW).

18. The semiconductor package method of claim 11, wherein the film can be pre-forming on the first shielding metal plate.

19. The semiconductor package method of claim 11, after providing the first shielding metal plate, further comprising:
a heating procedure;
wherein the heating procedure is heating the package for curing the film.
